(19) United States
(12) Patent Application Publication
(10) Pub. No.: US 2007/0205493 A1
(43) Pub. Date: Sep. 6, 2007

(54) Semiconductor package structure and method for manufacturing the same

(75) Inventors: Yueh-Ming Tung, Fengshan City (TW); Kuo-Yang Sun, Kaohsiung City (TW); Chia-Ming Yang, Tainan City (TW); Hung-Tai Mai, Yanchao Shiang (TW); Hui-Ying Hsu, Fengshan City (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: Orient Semiconductor Electronics, Ltd.

(21) Appl. No.: 11/450,996

(22) Filed: Jun. 12, 2006

(30) Foreign Application Priority Data
Mar. 6, 2006 (TW) 95107481

(51) Int. Cl. H01L 23/495

(52) U.S. Cl. 257/666

(57) ABSTRACT

A semiconductor package structure is disclosed. The structure includes a lead frame, a semiconductor chip, a plurality of metallic conducting wires, an encapsulation, a barrier layer and a pure tin layer, herein the lead frame has at least one die pad, a plurality of inner leads and outer leads. The semiconductor chip is disposed on the die pad. The metallic conducting wires electrically connect the semiconductor chip and the inner leads. The encapsulation packages of the semiconductor chip, the die pad, the metallic conducting wires and the inner leads. The barrier layer covers each of the outer leads to prevent an inter-metallic compound produced by the outer leads and pure tin. The pure tin layer covers the barrier layer to increase the solder wettability for the outer leads. Besides, a method for manufacturing the semiconductor package structure is disclosed.

### RELATED APPLICATIONS

The present application is based on, and claims priority from, Taiwan Application Serial Number 95107481, filed Mar. 06, 2006, the disclosure of which is hereby incorporated by reference herein in its entirety.

### FIELD OF THE INVENTION

The present invention relates to a semiconductor package structure and method for manufacturing the same, and more particularly, to a semiconductor package structure and a method of manufacture which can prevent whiskers produced on the outer leads of the lead frame after electroplating pure tin.

### BACKGROUND OF THE INVENTION

In the process of manufacturing semiconductors, an IC package step used to protect IC chips and provide the IC chips with external contacts for electrical connection is one of the important semiconductor manufacturing steps, herein the IC chip is installed in an IC lead frame. The IC lead frame can electrically connect the IC chip and a printed circuit board.

Referring to FIG. 1, FIG. 1 is a schematic flow diagram showing a conventional semiconductor package method to prevent the outer leads of the lead frame from producing whiskers. In the semiconductor package method 100, the steps sequentially include providing a lead frame 110, performing a semiconductor package 120, electroplating the lead frame 130, heating the lead frame 140 and cutting the lead frame 150, herein the lead frame is used to carry a plurality of semiconductor chips and the lead frame is often made of a metal with high conductivity, such as copper, a copper alloy or other alloys. In the step 120, the semiconductor chips are electrically connected with the inner leads of the lead frame and a molding step is used to form a plurality of encapsulations to package the semiconductor chips and the inner leads of the lead frame. In the step 130, a metal layer is electroplated on the outer leads of the lead frame, which are exposed out of the encapsulation, to protect the outer leads from being oxidized or corroded by environmental factors (e.g. moisture) and to simultaneously provide good solder wettability. In the step 140, metal diffusion between the metal layer and the outer leads is produced to eliminate metal stress so as to prevent the outer leads of the lead frame from producing whiskers. In the step 150, a plurality of semiconductor package structures are cut and separated to form a single semiconductor package structure. The material of the metal layer electroplated on the outer leads are pure tin, tin alloy, gold and so on, herein the pure tin and tin alloy are often used because they have better solder wettability and their cost is the lowest. In the conventional package process without a heating process, the electroplating layer made of pure tin will produce single crystal needle whiskers at the same time so as to cause a shorting problem. In the semiconductor package method 100 without producing whiskers, the heating treatment of step 140 and a method of adding lead in the pure tin are used to prevent the production of whiskers. However, lead is a poisonous metal. Although the tin-lead alloy can solve the problem of producing whiskers, it cannot follow the trend of the environmental requirements for electroplating without lead in future semiconductor packaging processes. Besides, the heating treatment in step 140 can probably destroy the semiconductor chips to reduce the productive yield and increase the cost.

### SUMMARY OF THE INVENTION

Therefore, an improved semiconductor package structure is needed to solve the problem of whiskers produced in the conventional structure so as to achieve the object of preventing whiskers from being produced.

Accordingly, one aspect of the present invention is to provide a semiconductor package structure, which includes a barrier layer added between a lead frame and a pure tin layer to prevent the lead frame and the pure tin from reacting to form whiskers, thereby solving the problem caused by the whiskers.

Another aspect of the present invention is to provide a method for manufacturing a semiconductor package structure, which performs an electroplating step to sequentially coat a barrier layer and a pure tin layer on the outer leads of the lead frame, thereby not only saving the additional heating treatment step but also simultaneously solving the problem caused by the whiskers and the heating treatment.

To achieve the aforementioned aspects, the present invention provides a semiconductor package structure. The semiconductor package structure includes a lead frame, a semiconductor chip, a plurality of metallic conducting wires, an encapsulation, a barrier layer and a pure tin layer, herein the lead frame has at least one die pad, a plurality of inner leads and outer leads. The semiconductor chip is disposed on the die pad. The metallic conducting wires electrically connect the semiconductor chip and the inner leads. The encapsulation packages of the semiconductor chip, the die pad, the metallic conducting wires and the inner leads. The barrier layer covers each of the outer leads to prevent an inter-metallic compound from being produced by the outer leads and pure tin, herein the barrier layer is made of an environmentally friendly material without a heavy metal and has good solder wettability with the outer leads and the pure tin. The pure tin layer covers the barrier layer to increase the solder wettability for the outer leads.

To achieve the aforementioned aspects, the present invention provides a method for manufacturing a semiconductor package structure. In the method, a lead frame is provided first, herein the lead frame has at least one die pad, a plurality of inner leads and outer leads. A semiconductor package step is then performed to dispose at least one semiconductor chip on the die pad, and an encapsulation is used to package the semiconductor chip, the die pad and the inner leads after electrically connecting the semiconductor chip and the inner leads. A barrier layer is then formed on the outer leads to prevent the outer leads and the pure tin from forming an inter-metallic compound, herein the barrier layer is an environmentally friendly material without a heavy metal. A pure tin layer is formed on the barrier layer to increase the solder wettability for the outer leads.

According to the embodiment of the present invention, the materials of the above-mentioned barrier layer include pure nickel, pure titanium or chromium (VI).

According to the embodiment of the present invention, the materials of the above-mentioned lead frame include pure copper or a copper alloy.

With the application of the above-mentioned semiconductor package structure, a barrier layer is directly formed on the outer leads of the lead frame to prevent the lead frame and the pure tin from being in contact and reacting to form an inter-metallic compound. Compared with other conventional structures, the present invention can effectively prevent whiskers from producing so as to solve the problem caused by the whiskers. Besides, with the application of the above-mentioned method for manufacturing semiconductor package structures, an electroplating step is used to form the barrier layer and the pure tin layer, which can not only save a heating treatment step, but also simultaneously solves the problem caused by the whiskers and the heating treatment.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1 is a schematic flow diagram showing a conventional semiconductor package method to prevent the outer leads of the lead frame from producing whiskers;

FIG. 2 is a schematic flow diagram showing a semiconductor package method of the preferred embodiment of the present invention; and

FIGS. 3A-3D are a series of cross-sectional schematic diagrams of a semiconductor package structure of the preferred embodiment of the present invention.

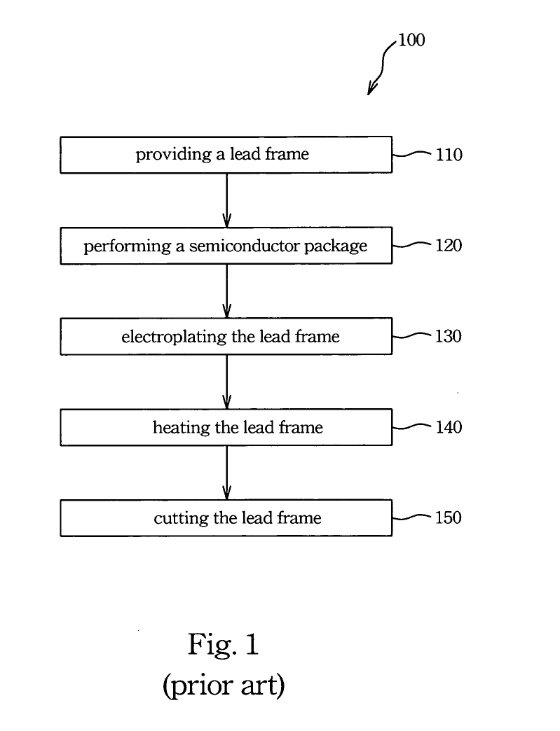

### DETAILED DESCRIPTION OF THE PREFERRED EMBODIMENT

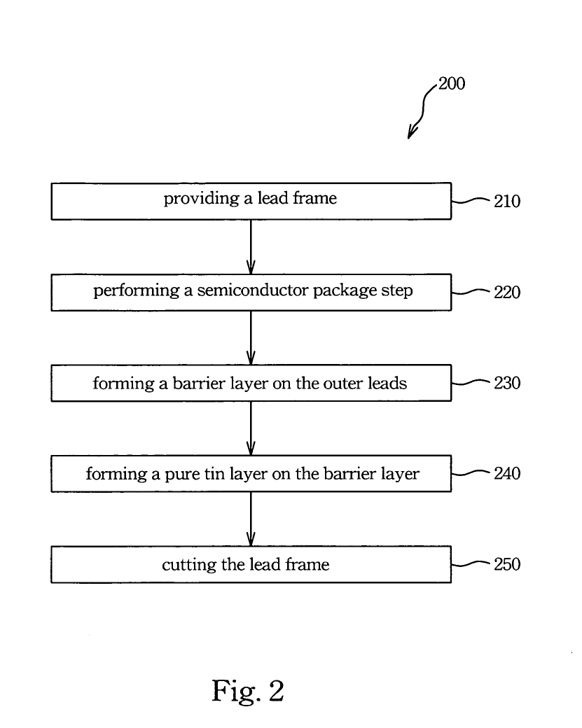

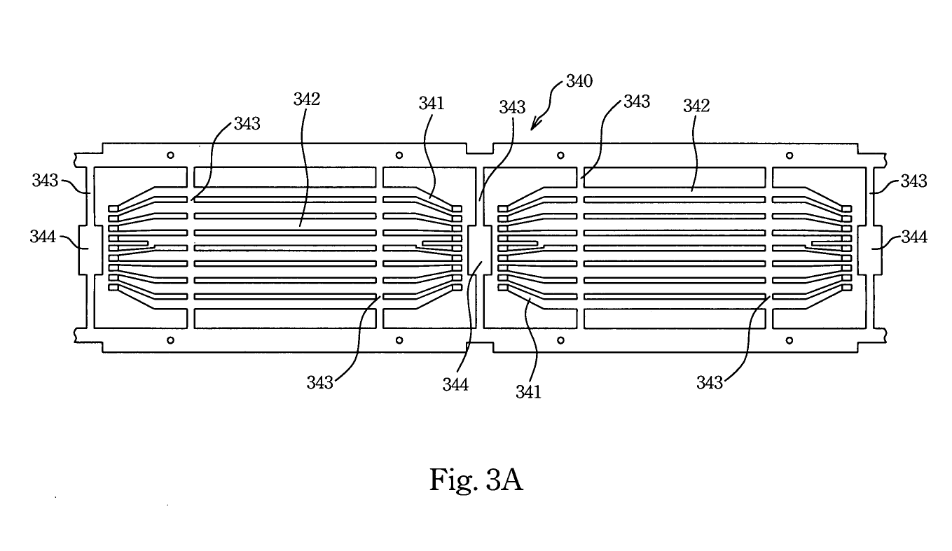

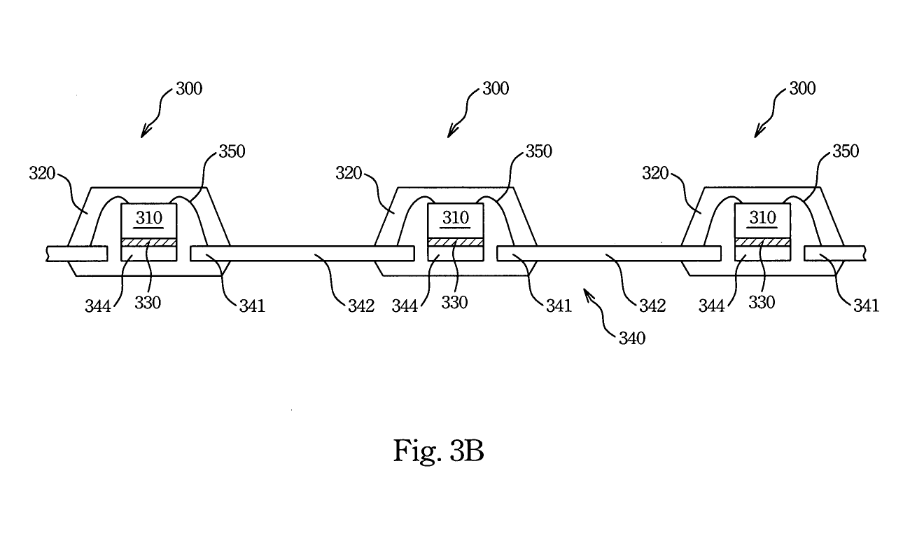

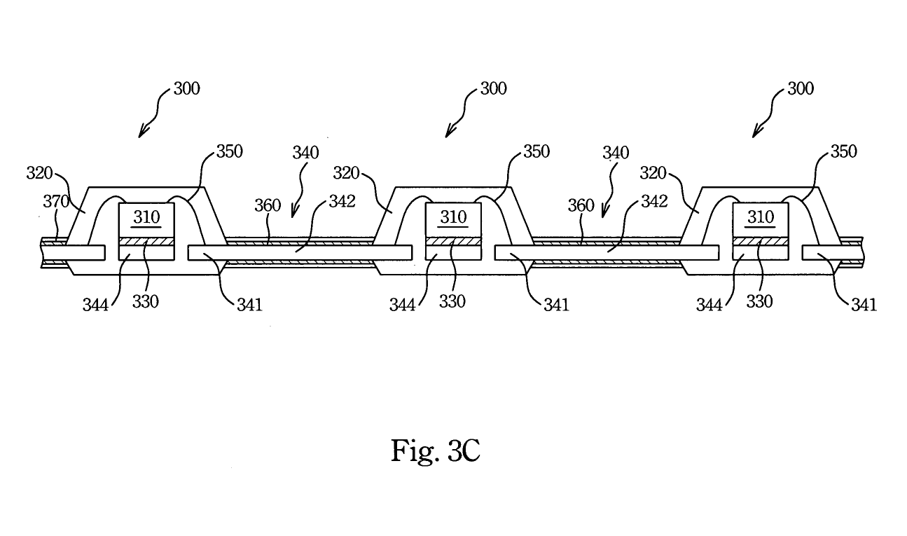

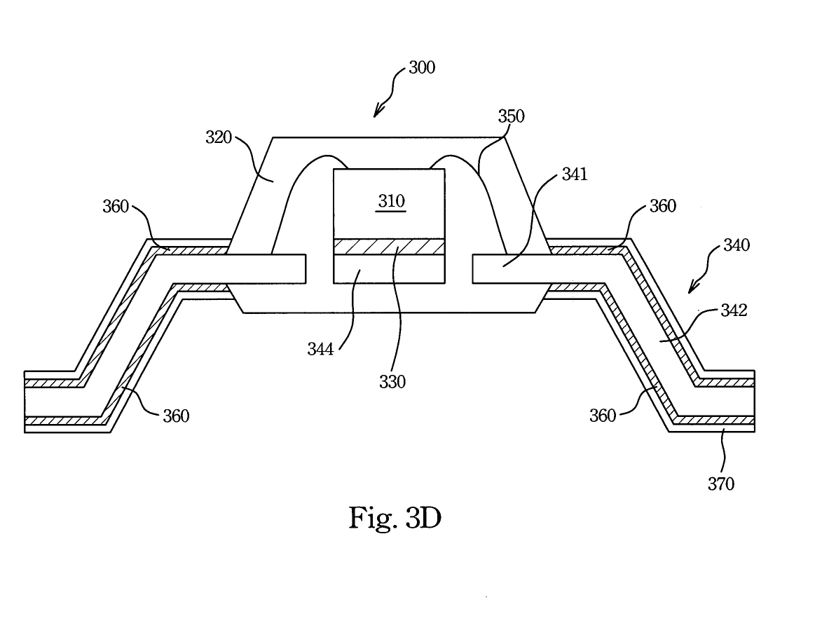

FIG. 2 is a schematic flow diagram showing a semiconductor package method of the preferred embodiment of the present invention and FIGS. 3A-3D are a series of cross-sectional schematic diagrams of a semiconductor package structure of the preferred embodiment of the present invention. In the semiconductor package method 200, the steps sequentially include providing a lead frame 210, performing a semiconductor package step 220, forming a barrier layer on the outer leads 230, forming a pure tin layer on the barrier layer 240 and cutting the lead frame 250. Firstly, as shown in FIG. 2 and FIG. 3A, the step 210 provides a lead frame 340. The lead frame 340 includes a plurality of inner leads 341, outer leads 342, tie bars 343 and die pads 344, herein the inner leads 341 are used to electrically connect the semiconductor chips 310, the outer leads 342 are used to electrically connect the printed circuit boards (not shown), and the tie bars 343 are used to fix the outer leads 342 and the die pads 344. In the embodiment, the lead frame 340 is a metal containing copper, such as pure copper or a copper alloy.

Next, as shown in FIG. 2 and FIG. 3B, the step 220 of performing a semiconductor package step is performed. The lead frame 340 is used to be a carrier for a plurality of semiconductor chips 310. A bottom surface (not shown) of the semiconductor chip 310 is fixed on a top surface (not shown) of the die pad 344 by an adhesive tape 330 and a conventional wire bonding technology is then used to electrically connect the semiconductor chip 310 and the inner leads 341 with metal conducting wires 350. A molding step or other method is then used to form a plurality of encapsulations 320 to package the semiconductor chip 310, the die pad 344, the inner lead 341 and the metal conducting wires 350.

Thereafter, as shown in FIG. 2 and FIG. 3C, the step 230 of forming a barrier layer on the outer leads is performed. A barrier layer 360 is formed on the surface of the outer leads 342 exposed out of the encapsulation 320 to prevent the outer lead 342 and the pure tin from producing an inter-metallic compound, herein the barrier layer 360 is an environmentally friendly material without any heavy metal, such as pure nickel, pure titanium or chromium (VI). In the embodiment, the barrier layer 360 is formed by electroplating, without limitation, any other method (such as sputter) can also be used. Next, as shown in FIG. 2 and FIG. 3C, the step 240 of forming a pure tin layer on the barrier layer is performed. A pure tin layer 370 is formed on the barrier layer 360 to increase the solder wettability for the outer leads 342. In the embodiment, a method for forming the pure tin layer 370 is such as electroplating, without limitation, any other method (such as sputter) can also be used.

Next, as shown in FIG. 2 and FIG. 3D, the step 250 of cutting the lead frame is performed. The step 250 includes a singularizing process, a trimming process and a bending process, herein the singularizing process is that a plurality of semiconductor package structures 300 packaged on the lead frame 340 are cut into single package units and the tie bars 343 of the lead frame 340 are removed. The outer lead 342 exposed out of the encapsulation 320 is then bent to I-lead, J-lead, C-lead or gull wing to make the semiconductor package structure 300 electrically connect to the printed circuit board (not shown) by the outer lead 342.

Accordingly, the characteristic of the semiconductor package structure of the present invention is to add a barrier layer between the lead frame and the pure tin layer to prevent the lead frame and the pure tin layer from contacting and reacting to form an inter-metallic compound. Compared with other conventional structures, the present invention can effectively prevent whiskers from forming so as to solve the problem caused by the whiskers. Besides, with the application of the above-mentioned method for manufacturing semiconductor package structures, an electroplating step is used to form the barrier layer and the pure tin layer, which not only saves the heating treatment step, but also solves the problem caused by the whiskers and the heating treatment.

In general, the advantage of applying the method for manufacturing the semiconductor package structure of the present invention is that the additional barrier layer formed in the semiconductor package structure does not need an additional process or machine. Only an electroplating tank needs to be added in the conventional electroplating process to electroplate the barrier layer and to complete the semiconductor package structure of the present invention. Compared with the conventional method, the method for manufacturing the semiconductor package structure of the present invention not only saves a heating treatment step, but also simultaneously achieves the objective of the conventional method without changing the conventional manufacturing process.

As is understood by a person skilled in the art, the foregoing preferred embodiments of the present invention are illustrated of the present invention rather than limiting of the present invention. It is intended to cover various modifications and similar arrangements included within the spirit and scope of the appended claims, the scope of which should be accorded the broadest interpretation so as to encompass all such modifications and similar structure.

What is claimed is:

1. A semiconductor package structure, comprising:
a lead frame, wherein said lead frame includes a plurality of inner leads and outer leads;
a semiconductor chip disposed on said lead frame, wherein said semiconductor chip is electrically connected to said inner leads;
an encapsulation used to package said semiconductor-chip and said inner leads;
a barrier layer covering each of said outer leads to prevent said outer leads and a pure tin from producing an inter-metallic compound, wherein said barrier layer is an environmentally friendly material without any heavy metal and has a good solder wettability with said outer leads and said pure tin; and
a pure tin layer covering said barrier layer.

2. The semiconductor package structure of claim 1, wherein said barrier layer is made of pure nickel, pure titanium or chromium (VI).

3. The semiconductor package structure of claim 2, wherein said lead frame is made of pure copper or a copper alloy.

4. The semiconductor package structure of claim 2, further comprising:
a plurality of metal conducting wires electrically connecting said semiconductor chip and said inner leads.

5. The semiconductor package structure of claim 2, wherein said lead frame further comprises a die pad to carry said semiconductor chip.

6. The semiconductor package structure of claim 1, wherein said lead frame is made of pure copper or a copper alloy.

7. The semiconductor package structure of claim 1, further comprising:
a plurality of metal conducting wires electrically connecting said semiconductor chip and said inner leads.

8. The semiconductor package structure of claim 1, wherein said lead frame further comprises a die pad to carry said semiconductor chip.

9. A method for manufacturing a semiconductor package structure, said method comprising:
providing a lead frame, wherein said lead frame includes a plurality of inner leads and outer leads;
performing a semiconductor package step to dispose at least a semiconductor chip on said lead frame, wherein said semiconductor chip and said inner leads are packaged by an encapsulation after electrically connecting said semiconductor chip and said inner leads;
forming a barrier layer on each of said outer leads to prevent said outer leads and pure tin from forming an inter-metallic compound, wherein said barrier layer is an environmentally friendly material without any heavy metal; and
forming a pure tin layer on said barrier layer.

10. The method of claim 9, further comprising:
cutting said lead frame to form a single package structure of one semiconductor chip.

11. The method of claim 10, wherein said barrier layer is made of pure nickel, pure titanium or chromium (VI).

12. The method of claim 10, wherein said lead frame is made of pure copper or a copper alloy.

13. The method of claim 10, wherein a method for forming said barrier layer is an electroplating method.

14. The method of claim 10, wherein a method for forming said pure tin layer is an electroplating method.

15. The method of claim 10, wherein said semiconductor chip is disposed on a die pad of said lead frame.

16. The method of claim 10, wherein said outer leads are bent to I-lead, J-lead, C-lead or a gull wing in the step of cutting said lead frame.

17. The method of claim 9, wherein said barrier layer is made of pure nickel, pure titanium or chromium (VI).

18. The method of claim 9, wherein said lead frame is made of pure copper or a copper alloy.

19. The method of claim 9, wherein a method for forming said barrier layer is an electroplating method.

20. The method of claim 9, wherein a method for forming said pure tin layer is an electroplating method.
